(19) United States
(12) Patent Application Publication
(10) Pub. No.: US 2026/0068142 A1
(43) Pub. Date: Mar. 5, 2026

(54) SEMICONDUCTOR STRUCTURE AND METHOD FOR FORMING THE SAME

(71) Applicant: Powerchip Semiconductor Manufacturing Corporation, Hsinchu (TW)

(72) Inventors: Li-Peng Chang, Hsinchu City (TW); San-Jung Chang, Hsinchu City (TW)

(73) Assignee: Powerchip Semiconductor Manufacturing Corporation, Hsinchu (TW)

(21) Appl. No.: 18/906,127

(22) Filed: Oct. 3, 2024

(30) Foreign Application Priority Data
Aug. 29, 2024 (TW) 113132669

(51) Int. Cl. H10B 12/00; H01L 21/768; H01L 23/528

(52) U.S. Cl. CPC H10B 12/488; H10W 20/056; H10W 20/435

(57) ABSTRACT

The disclosure provides a semiconductor structure and a method for forming the same. The semiconductor structure includes a substrate including a cell region and a pick-up region adjacent to the cell region, word lines embedded in the substrate, arranged in a first direction, extending in a second direction crossing the cell region and the pick-up region, and each including a first segment in the cell region and a second segment in the pick-up region, an insulation layer embedded in the substrate on each word line and, and a conductive contact on the second segment of each word line. The first segment includes a first top surface contacting the insulation layer. The second segment includes a second top surface contacting the conductive contact and a third top surface contacting the insulation layer. The second top surface has a level height different from a level height of the first top surface.

### CROSS-REFERENCE TO RELATED APPLICATION

This application claims the priority benefit of Taiwan application serial no. 113132669, filed on August 29, 2024. The entirety of the above-mentioned patent application is hereby incorporated by reference herein and made a part of this specification.

### BACKGROUND

### Technical Field

The present invention relates to a semiconductor structure and a method for forming the same, and particularly relates to a word line for a memory device and a method for forming the same.

### Description of Related Art

As the dimensions of electronic devices continue to shrink and users' demands for the performance of the electronic devices continue to increase, how to include more elements in the electronic devices while maintaining the existing horizontal area, or how to have a compact horizontal area while maintaining the existing number of the elements, is one of the goals that a skilled person in the field are eager to achieve. However, the gap between wires (e.g., the gap between the word lines) in either of situations will be shrunk, so that the gap or the spacing between the conductive contact (e.g., word line contacts) directly contacting the wire and the other wire adjacent thereto will be shrunk as well. As a result, it is much stricter for the conductive contacts in terms of the critical dimension (CD) and overlay requirements, and thereby resulting a problem of insufficient process margin.

### SUMMARY

The present invention provides a semiconductor structure and a method of forming the same in which the second section of the word line in the pick-up region are designed to include a portion having a different level height from the first section of the word line in the cell region. As such, the gap or the spacing between the conductive contact in contact with the portion of the word line and the other word lines adjacent thereto can be improved, and thereby lowering the critical dimension (CD) and overlay requirements for the conductive contact, so as to enhance the process margin of the conductive contact.

An embodiment of the present invention provides a semiconductor structure including a substrate, a plurality of word lines, an insulation layer, and a conductive contact. The substrate includes a cell region and a pick-up region adjoining the cell region. The word lines are arranged in a first direction and extending in a second direction different from the first direction. The word lines are embedded in the substrate and cross the cell region and the pick-up region, and each word line includes a first section located in the cell region and a second section located in the pick-up region. The insulation layer is disposed on each word line and embedded in the substrate. The conductive contact is disposed on the second section of each word line. The first section includes a first top surface in contact with the insulation layer. The second section includes a second top surface in contact with the conductive contact and a third top surface in contact with the insulation layer, wherein a level height of the second top surface is different from a level height of the first top surface.

In some embodiments, the level height of the second top surface is higher than the level height of the first top surface.

In some embodiments, the level height of the second top surface is different from a level height of the third top surface.

In some embodiments, the level height of the second top surface is higher than the level height of the third top surface.

In some embodiments, a dimension of each word line in the first direction gradually decreases along a third direction away from a top surface of the substrate.

In some embodiments, the level height of the second top surface is lower than the level height of the first top surface.

In some embodiments, the level height of the second top surface is the same as the level height of the third top surface.

In some embodiments, the second section may include a first portion in contact with the insulation layer and a second portion protruding from the first portion, being in contact with the conductive contact, and surrounded by the insulation layer.

An embodiment of the present invention provides a method for forming a semiconductor device, which includes the following steps. A substrate including a cell region and a pick-up region adjoining the cell region is provided. A plurality of word lines arranged in a first direction and extending in a second direction different from the first direction are formed in the substrate. Each word line crosses the cell region and the pick-up region and includes a first section formed in the cell region and a second section formed in the pick-up region. An insulation layer embedded in the substrate is formed on each word line. A conductive contact is formed on the second section of each word line. The first section includes a first top surface in contact with the insulation layer. The second section includes a second top surface in contact with the conductive contact and a third top surface in contact with the insulation layer, and a level height of the second top surface is different from a level height of the first top surface.

In some embodiments, a step of forming the word lines includes: forming a plurality of word line trenches in the substrate, wherein the word line trenches are arranged in the first direction and extending in the second direction, and each word line trench crosses the cell region and the pick-up region; filling a word line material layer in each word line trench; forming a mask pattern on the word line material layer in each word line trench, so as to cover a portion of the word line material layer corresponding to a position of the conductive contact; and removing a portion of the word line material layer exposed by the mask pattern to form the plurality of word lines.

In some embodiments, a step of forming the word lines includes: forming a plurality of word line trenches in the substrate, wherein the word line trenches are arranged in the first direction and extending in the second direction, and each word line trench crosses the cell region and the pick-up region; filling a word line material layer in each word line trench; forming a mask pattern covering a portion of the word line material layer in each word line trench located in the cell region; and removing a portion of the word line material layer exposed by the mask pattern located in the pick-up region to form the plurality of word lines.

In some embodiments, the level height of the second top surface is higher than the level height of the first top surface.

In some embodiments, the level height of the second top surface is different from a level height of the third top surface.

In some embodiments, the level height of the second top surface is higher than the level height of the third top surface.

In some embodiments, a dimension of each word line in the first direction is formed to gradually decrease in a third direction away from a top surface of the substrate.

In some embodiments, the level height of the second top surface is lower than the level height of the first top surface.

In some embodiments, the level height of the second top surface is the same as a level height of the third top surface.

In some embodiments, the second section includes a first portion in contact with the insulation layer and a second portion protruding from the first portion, being in contact with the conductive contact, and surrounded by the insulation layer.

Based on the above, in the aforementioned semiconductor structure and the method for forming the same, the second sections of the word lines in the pick-up region are designed to include a portion having a different level height from the first sections of the word lines in the cell region. As such, the gap or the spacing between the conductive contact in contact with the portion of the word line and other word line adjacent thereto can be improved, and thereby lowering the critical dimension (CD) and overlap requirements for the conductive contact, so as to enhance the process margin of the conductive contact.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram illustrating a top view of a semiconductor structure according to an embodiment of the present invention.

FIG. 2A and FIG. 2B are respectively schematic cross-sectional views taken along line X-X' and line Y-Y' in FIG. 1 according to an embodiment of the present invention.

FIG. 3A and FIG. 3B are respectively schematic cross-sectional views taken along lines X-X' and Y-Y' in FIG. 1 according to another embodiment of the present invention.

FIG. 4A to FIG. 4C are schematic diagrams illustrating cross-sectional views for forming a semiconductor structure according to an embodiment of the present invention.

FIG. 5 is a schematic diagram illustrating a top view of FIG. 4C.

FIG. 6, FIG. 7, and FIG. 8A to FIG. 8C are schematic diagrams for forming a semiconductor structure according to another embodiment of the present invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are omitted in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being "on" or "connected" to another element, it may be directly on or connected to the other element or intervening elements may be present. If an element is referred to as being "directly on" or "directly connected" to another element, there are no intervening elements present. As used herein, "connection" may refer to both physical and/or electrical connections, and "electrical connection" or "coupling" may refer to the presence of other elements between two elements.

As used herein, "about", "approximately" or "substantially" includes the values as mentioned and the average values within the range of acceptable deviations that can be determined by those of ordinary skill in the art. Consider to the specific amount of errors related to the measurements (i.e., the limitations of the measurement system), the meaning of "about" may be, for example, referred to a value within one or more standard deviations of the value, or within ±30%, ±20%, ±10%, ±5%. Furthermore, the "about", "approximate" or "substantially" used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

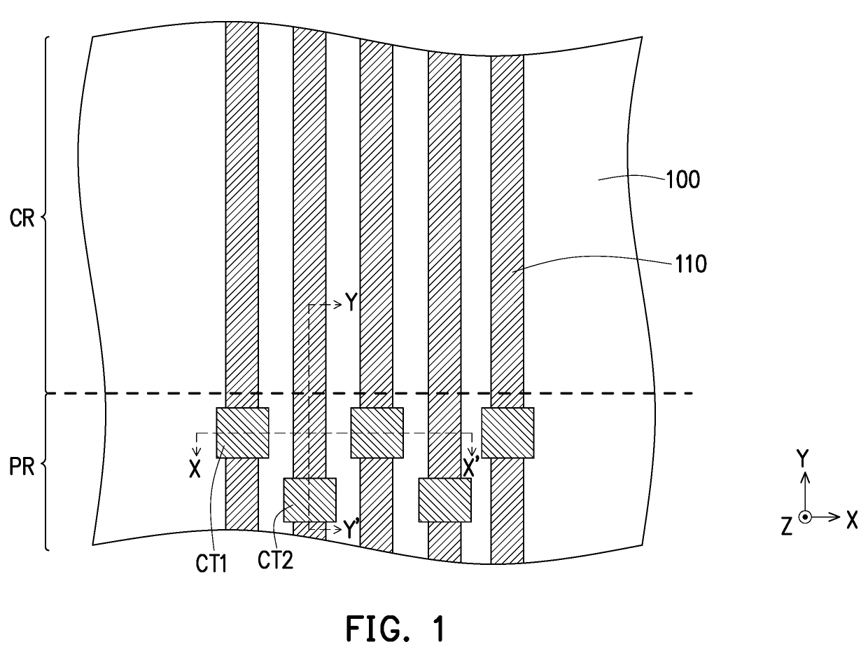

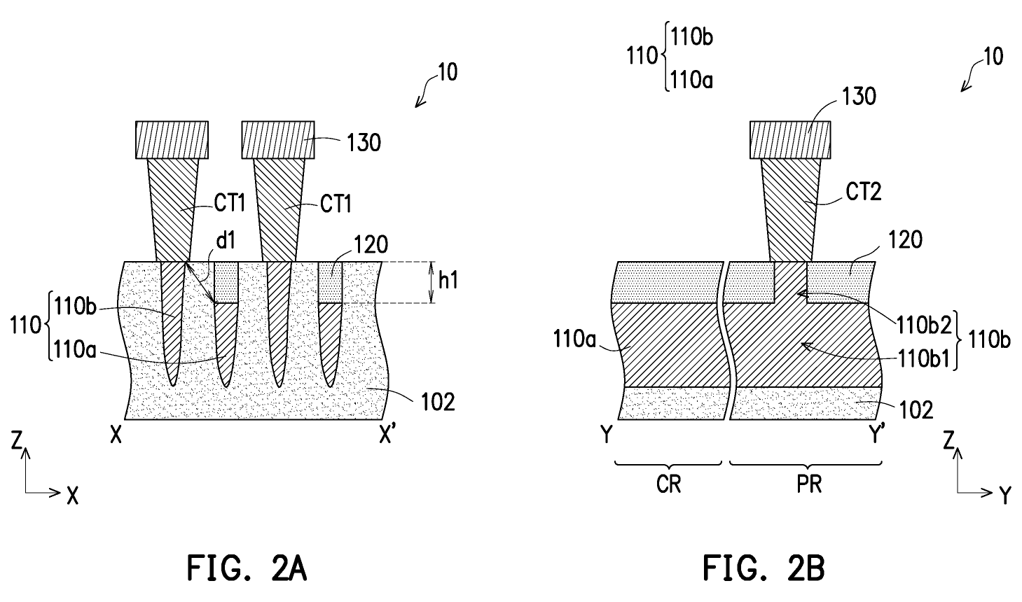

FIG. 1 is a schematic diagram illustrating a top view of a semiconductor structure according to an embodiment of the present invention. FIG. 2A and FIG. 2B are respectively schematic cross-sectional views taken along line X-X' and line Y-Y' in FIG. 1 according to an embodiment of the present invention.

Referring to FIG. 1 and FIG. 2A and FIG. 2B, the semiconductor structure 10 includes a substrate 100, a plurality of word lines 110, an insulation layer 120, and conductive contact CT1 or CT2.

The substrate 100 may include a cell region CR and a pick-up region PR adjoining the cell region CR. The substrate 100 may include a semiconductor substrate or a semiconductor-on-insulator (SOI) substrate, or a device layer formed on the semiconductor substrate or the SOI substrate. The cell region CR may be a region where memory cells are formed. For example, the cell region CR may be a cell region where volatile dynamic random-access memory (DRAM) cells are formed. The pick-up region PR may be a region where conductive contacts are formed to pick up the electrical signals of wires (e.g., word lines) formed in the substrate 100. In some embodiments, the substrate 100 may include an isolation structure 102. The isolation structure 102 may include any material suitable for the isolation structure such as silicon oxide. In some embodiments, the isolation structure 102 may be a shallow trench isolation (STI) structure.

The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be p-type, whereas the second conductivity type may be n-type.

The device layer may include active devices such as N-type metal-oxide-semiconductor (NMOS), P-type metal-oxide-semiconductor (PMOS), or complementary metal-oxide-semiconductor (CMOS). In some embodiments, the active devices may be disposed in the cell region CR, but is not limited thereto.

The word lines 110 are arranged in a first direction (e.g., a direction X shown in FIG. 1) and each extends in a second direction (e.g., a direction Y shown in FIG. 1) different from the first direction. In some embodiments, the first direction intersects with the second direction. In some embodiments, the first direction is perpendicular to the second direction. Each word line 110 is embedded in the substrate 100 and crosses the cell region CR and the pick-up region PR. Each word line 110 includes a first section located in the cell region CR and a second section located in the pick-up region PR. The word lines 110 may include conductive materials such as metals or metal alloys. The metals and the metal alloys may be, for example, Cu, Al, Ti, Ta, W, Pt, Cr, Mo, or alloys thereof. In some embodiments, the portions of the word lines 110 shown in FIG. 2A and FIG. 2B are formed in the isolation structure 102 of the substrate 100.

The insulation layer 120 is disposed on each word line 110 and is embedded in the substrate 100. In some embodiments, the insulation layer 120 is embedded in the substrate 100 in the pick-up region PR and in the cell region CR. The portions of the insulation layer 120 shown in FIG. 2A and FIG. 2B are embedded in the isolation structure 102 of the substrate 100. The insulation layer 120 may include insulation materials such as nitrides (e.g., silicon nitride).

The conductive contact CT1 or CT2 are disposed on the second section of each word line 110. The conductive contact CT1 or CT2 may include conductive materials such as metals or metal alloys. The metals and the metal alloys may be, for example, Cu, Al, Ti, Ta, W, Pt, Cr, Mo, or alloys thereof. In some embodiments, the conductive contact CT1 and the conductive contact CT2 may be arranged alternately offset from each other along the first direction (e.g., direction X), and thereby increasing the distance between the neighboring conductive contacts CT1 and CT2, so that the requirement for the critical dimension (CD) of the conductive contact and the overlay requirement for the conductive contact can be reduced, and thus the process margin for the conductive contact can be enhanced.

As shown in FIG. 2A and FIG. 2B, the first sections of the word lines 110 include first top surfaces in contact with the insulation layer 120, and the second sections of the word lines 110 include second top surfaces in contact with the conductive contacts CT1 and CT2 and third top surfaces in contact with the insulation layer 120. The level heights of the second top surfaces in contact with the conductive contacts CT1 and CT2 in the second sections of the word lines 110 are designed to be different from the level heights of the first top surfaces in contact with the insulation layer 120 in the first sections of the word lines 110. As a result, the gaps (e.g., distances d1 shown in FIG. 2A) between the conductive contacts (e.g., the conductive contacts CT1 shown in FIG. 2A) and the neighboring word lines 110 may be enhanced, and thereby lowering the requirements for the critical dimensions (CD) of the conductive contacts CT1 and the overlay requirements for the conductive contacts CT1, so that the process margin for the conductive contacts CT1 may be enhanced.

In this embodiment, as shown in FIG. 2A, the level heights of the second top surfaces in contact with the conductive contacts CT1 in the second sections of the word lines 110 are designed to be higher than the level heights of the first top surfaces in contact with the insulation layer 120 in the first sections of the word lines 110. As such, the gaps (e.g., distances d1 shown in FIG. 2A) between the conductive contacts CT1 and the neighboring word lines 110 may be enhanced, and thereby lowering the requirements for the critical dimensions (CD) of the conductive contacts CT1 and the overlay requirements for the conductive contacts CT1, so that the process margin for the conductive contacts CT1 may be enhanced. For example, in the case where the line widths of the word lines 110 are about 19 nm, the aforementioned distances may be increased by 2.4 times compared to the original.

In this embodiment, the level heights of the second top surfaces in contact with the conductive contacts CT1 in the second sections of the word lines 110 are different from the level heights of the third top surfaces in contact with the insulation layer 120 in the second sections of the word lines 110. As shown in FIG. 1 and FIG. 2B, the level heights of the second top surfaces in contact with the conductive contacts CT2 in the second sections of the word lines 110 are higher than the level heights of the third top surfaces in contact with the insulation layer 120 in the second sections of the word lines 110.

In this embodiment, as shown in FIG. 1 and FIG. 2A and FIG. 2B, in the cell region CR, the insulation layer 120 may be disposed in the word line trenches where the word lines 110 are formed, so as to cover the word lines 110. That is, the word lines 110 in the first sections of the cell region CR may be covered by the insulation layer 120 and may have the same level height (e.g., the level height that differs from the top surface of the isolation structure 102 of the substrate 100 by a height h1). In the pick-up region PR, the word lines 110 may include first portions 110a and second portions 110b. The first portions 110a of the word lines 110 may extend from the cell region CR and may have the same level height as the first sections of the word lines 110 in the cell region CR, and the first portions 110a of the word lines 110 are also covered by the insulation layer 120. The second portions 110b of the word lines 110 may include line portions 110b1 extending from the cell region CR and having the same level height as the first sections of the word lines 110 in the cell region CR and protrusion portions 110b2 protruding from the line portions 110b1, being in contact with the conductive contacts CT1 and CT2, and surrounded by the insulation layer 120.

In some embodiments, as shown in FIG. 2A and FIG. 2B, the semiconductor structure 10 may further include a wiring layer 130. In some embodiments, the wiring layer 130 may be, for example, a conductive layer of an interconnection layer formed by a back-end-of-line (BEOL) process. The material of the wiring layer 130 may include a conductive material such as a metal or a metal alloy. The metal and the metal alloy may be, for example, Cu, Al, Ti, Ta, W, Pt, Cr, Mo or alloys thereof. In some embodiments, the interconnection layer where the wiring layer 130 is formed may include a dielectric layer (not shown). The conductive contacts CT1 and CT2 and/or the wiring layer 130 may be formed in the dielectric layer. The dielectric layer may include oxides such as a tetraethyl orthosilicate (TEOS), a borophosphosilicate glass (BPSG), an oxide formed by a high density plasma (HDP), an undoped silicate glass (USG), a phosphosilicate glass (PSG), an oxide formed by a spin-coating manner such as a spin on glass (SOG) and a spin on dielectric (SOD), and an oxide formed by a high aspect ratio process (HARP).

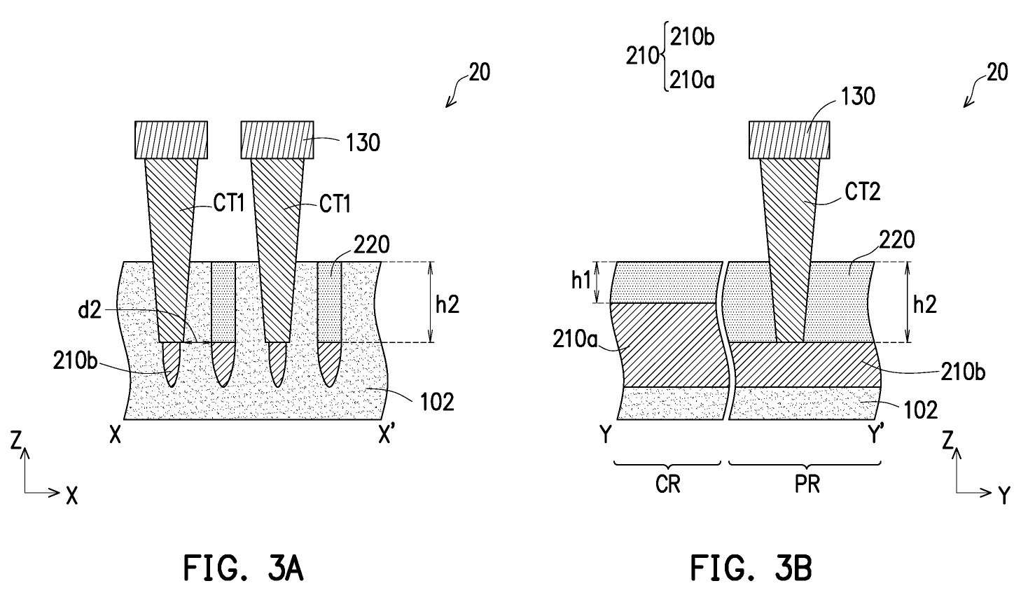

FIG. 3A and FIG. 3B are respectively schematic cross-sectional views taken along lines X-X' and Y-Y' in FIG. 1 according to another embodiment of the present invention. The semiconductor structure 20 shown in FIG. 3A and FIG. 3B is similar to the semiconductor structure 10 shown in FIG. 2A and FIG. 2B, the differences therebetween are mainly relied on the word lines 210 and the insulation layer 220 of the semiconductor structure 20 being different from the word lines 110 and insulation layer 120 of the semiconductor structure 10. Other identical or similar parts are denoted by the same or similar reference numerals, and will not be repeated hereinafter.

In this embodiment, as shown in FIG. 2A and FIG. 3A, the dimension of each word line 210 in the first direction (e.g., direction X) gradually decreases along a third direction (e.g., direction Z) away from the top surface of the substrate 100 (e.g., the top surface of the isolation structure 102). In other words, the distance between the adjacent word lines 210 gradually increases along the direction away from the top surface of the substrate 100. In this embodiment, as shown in FIG. 3A and FIG. 3B, the word lines 210 are designed to include first portions 210a in the cell region CR and second portions 210b in the pick-up region PR. The top surfaces of the second portions 210b are designed to be distanced from the top surface of the isolation structure 102 of the substrate 100 by a height h2 in which the height h2 is greater than the height h1 (the height h1 shown in FIG. 3B corresponds to the height h1 shown in FIG. 2A). As such, the distance (e.g., distance d2 shown in FIG. 3A) between the adjacent second portions 210b of the word lines 210 may be improved by increasing the height h2. For example, in the case where the line widths of the word lines 210 are about 19 nm, the aforementioned distances may be increased by 1.6 times compared to the original. In some embodiments, the word lines 110 shown in FIG. 2A have a lower contact resistance (Rc) than the word lines 210 shown in FIG. 3A.

In this embodiment, as shown in FIG. 3B, the first sections of the word lines 210 in the cell region CR may include first top surfaces in contact with the insulation layer 220, and the second sections of the word lines 210 in the pick-up region PR may include second top surfaces in contact with the conductive contacts CT2 and third top surfaces in contact with the insulation layer 220. The level heights of the second top surfaces of the word lines 210 in the second section in contact with the conductive contacts CT2 are designed to be lower than the level heights of the first top surfaces of the word lines 210 in the first sections in contact with the insulation layer 220. In this embodiment, as shown in FIG. 3B, in the pick-up region PR, the level heights of the second top surfaces of the word lines 210 in contact with the conductive contacts CT2 are the same as the level heights of the third top surfaces of the word lines 210 in contact with the insulation layer 220.

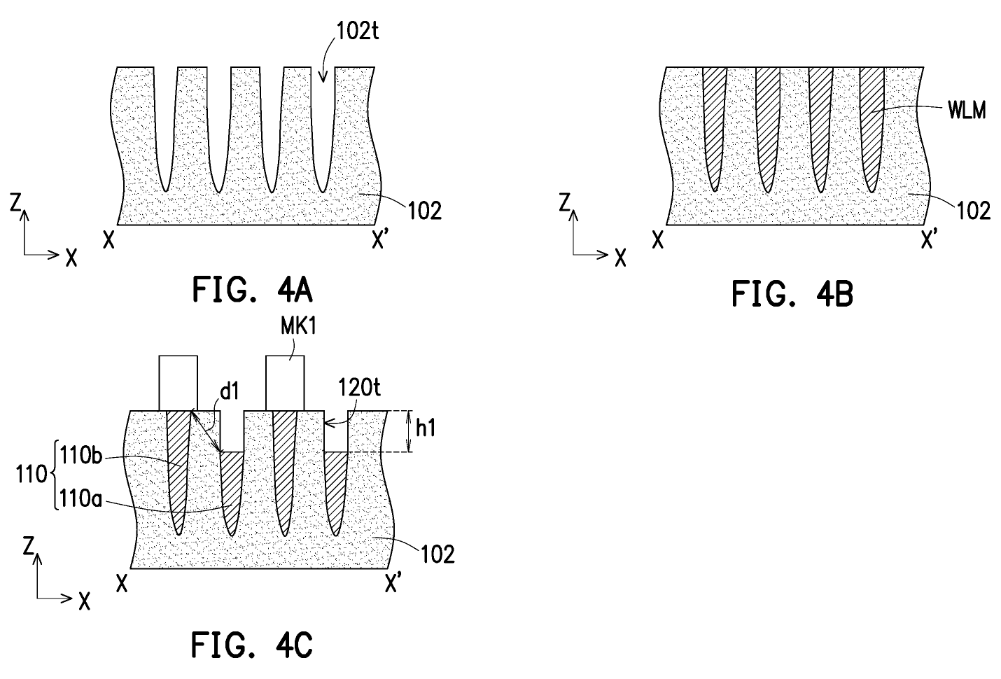

Hereinafter, a method of forming the semiconductor structure 10 shown in FIG. 2A and FIG. 2B will be illustrated with reference to FIGS. 4A to 4C, but is not limited thereto.

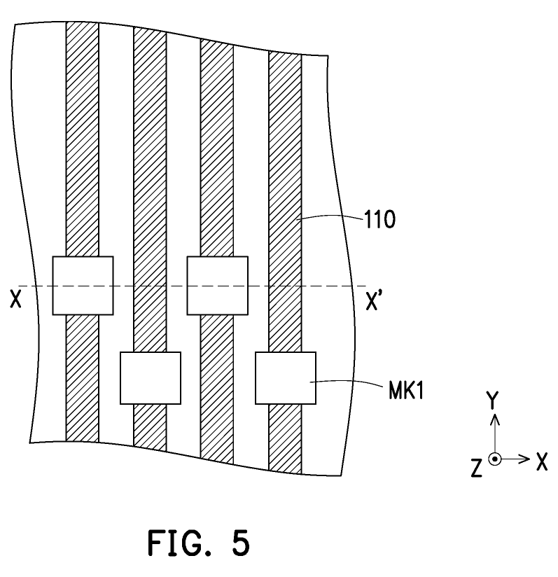

FIG. 4A to FIG. 4C are schematic diagrams illustrating cross-sectional views for forming a semiconductor structure according to an embodiment of the present invention. FIG. 5 is a schematic diagram illustrating a top view of FIG. 4C.

Firstly, a substrate 100 including a cell region CR and a pick-up region PR adjoining the cell region CR as shown in FIG. 1 is provided. In this embodiment, the substrate 100 may include an isolation structure 102.

Then, a plurality of word lines 110 are formed in the substrate 100. The word lines 110 are arranged in a first direction (e.g., direction X) and each extends in a second direction (e.g., direction Y) different from the first direction, wherein each word line 110 crosses the cell region CR and the pick-up region PR and includes a first section formed in the cell region CR and a second section formed in the pick-up region PR.

In some embodiments, the word lines 110 may be formed by the following manner.

Firstly, as shown in FIG. 4A, a plurality of word line trenches 102t are formed in the isolation structure 102 of the substrate 100. The word line trenches 102t are arranged in a first direction (e.g., direction X) and each extends in a second direction (e.g., direction Y) different from the first direction, wherein each word line trench 102t crosses the cell region CR and the pick-up region PR.

Next, as shown in FIG. 4B, word line material layers WLM are filled into the word line trenches 102t, respectively. The word line material layers WLM may include conductive materials such as metals or metal alloys. The metals and the metal alloys may be, for example, Cu, Al, Ti, Ta, W, Pt, Cr, Mo or alloys thereof.

Then, as shown in FIG. 4C and FIG. 5, mask patterns MK1 are respectively formed on the word line material layers WLM so as to cover the position of the word line material layers WLM corresponding to the conductive contacts CT1 and CT2 (please referring to FIG. 1 and FIG. 5 simultaneously). Afterwards, other portions of the word line material layers WLM exposed by the mask patterns MK1 are removed so as to form recesses 120t and the plurality of word lines 110.

In the cell region CR, the word line material layers WLM are exposed by the mask patterns MK1, so that the word lines 110 formed in the cell region CR are exposed by the recesses 120t.

In the pick-up region PR, the word line material layers WLM includes portions exposed by the mask patterns MK1 and portions covered by the mask patterns MK1, so that the word lines 110 formed in the pick-up region PR include first portions 110a exposed by the recesses 120t and second portions 110b covered by the mask patterns MK1. The first portions 110a of the word lines 110 may be extended from the cell region CR so that the level heights of the first portions 110a of the word lines 110 are the same as the level heights of the word lines 110 in the cell region CR. The second portions 110b of the word lines 110 may include line portions 110b1 and protrusion portions 110b2 protruding from the line portions 110b1 (as shown in FIG. 2B). The line portions 110b1 are extended from the cell region CR, so that the level heights of the line portions 110b1 are the same as the level heights of the word lines 110 in the cell region CR. The protrusion portions 110b2 are in contact with the mask patterns MK1 and are surrounded by the recesses 120t.

After that, the mask patterns MK1 are removed after the word lines 110 are formed.

Then, referring to FIG. 4C and FIG. 2A, an insulation material is filled into the recesses 120t to form an insulation layer 120 embedded in the substrate 100 on each word line 110. As shown in FIG. 2A, the insulation layer 120 is embedded in the isolation structure 102 of the substrate 100 in the pick-up region PR. Then, the conductive contacts CT1 and CT2 are formed on the second section of each word line 110 in the pick-up region PR.

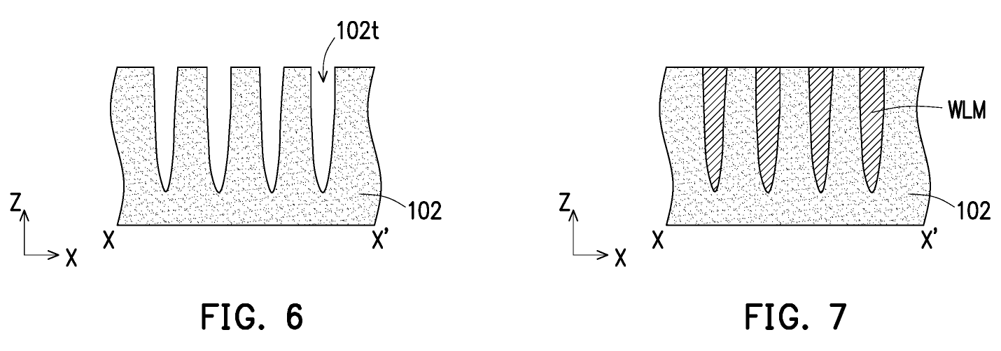

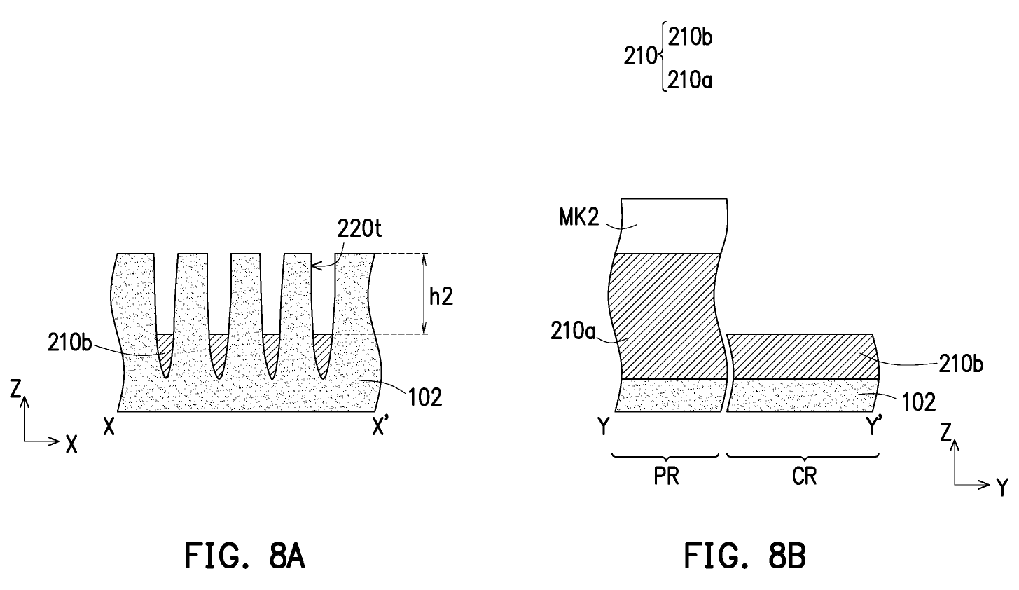

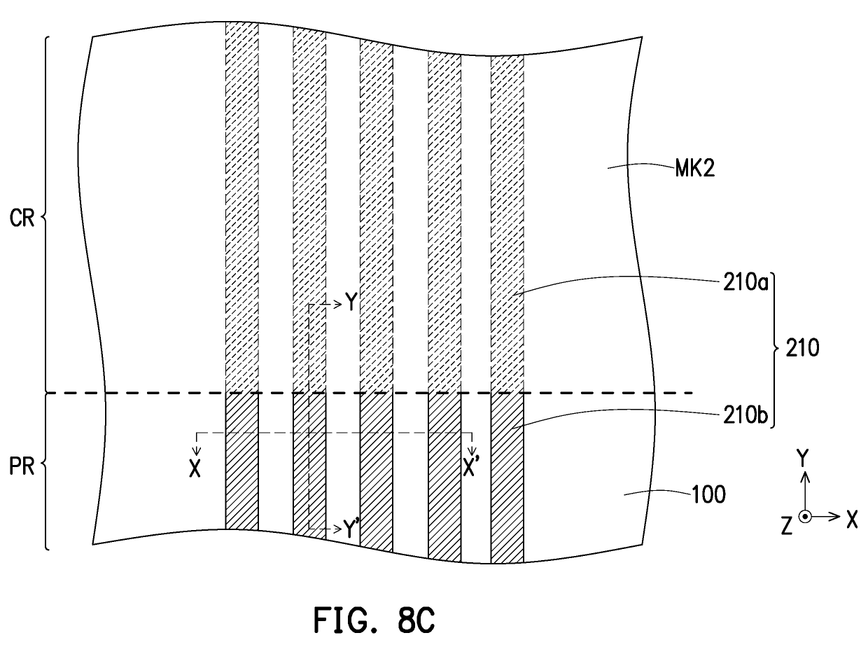

Hereinafter, a method of forming the semiconductor structure 20 shown in FIG. 3A and FIG. 3B will be illustrated with reference to FIGS. 6, 7 and 8A to 8C, but is not limited thereto.

FIG. 6, FIG. 7, and FIG. 8A to FIG. 8C are schematic diagrams for forming a semiconductor structure according to another embodiment of the present invention.

Firstly, a substrate 100 including a cell region CR and a pick-up region PR adjoining the cell region CR as shown in FIG. 1 is provided. In this embodiment, the substrate 100 may include an isolation structure 102.

Then, a plurality of word lines 110 are formed in the substrate 100. The word lines 110 are arranged in a first direction (e.g., direction X) and each extends in a second direction (e.g., direction Y) different from the first direction, wherein each word line 110 crosses the cell region CR and the pick-up region PR and includes a first section formed in the cell region CR and a second section formed in the pick-up region PR.

In some embodiments, the word lines 210 may be formed by the following manner.

Firstly, as shown in FIG. 6, a plurality of word line trenches 102t are formed in the isolation structure 102 of the substrate 100. The word line trenches 102t are arranged in a first direction (e.g., direction X) and each extends in a second direction (e.g., direction Y) different from the first direction, wherein each word line trench 102t crosses the cell region CR and the pick-up region PR.

Next, as shown in FIG. 7, word line material layers WLM are filled into the word line trenches 102t, respectively. The word line material layers WLM may include conductive materials such as metals or metal alloys. The metals and the metal alloys may be, for example, Cu, Al, Ti, Ta, W, Pt, Cr, Mo or alloys thereof.

Then, as shown in FIG. 8A to FIG. 8C, a mask pattern MK2 is formed on the word line material layers WLM to cover the portions of the word line material layers WLM located in the cell region CR (please referring to FIG. 8A to FIG. 8C simultaneously). Next, the portions of the word line material layers WLM exposed by the mask pattern MK2 and located in the pick-up region PR are removed to form recesses 220t and the plurality of word lines 210.

In the cell region CR, the word line material layers WLM are covered by the mask pattern MK2, so that the word lines 210 in the cell region CR are formed to include first portions 210a in contact with the mask pattern MK2. In the pick-up region PR, the word line material layers WLM are exposed by the mask pattern MK2, so that the word lines 210 in the pick-up region PR are formed to include second portions 210b where the recesses 220t are formed thereon.

After that, the mask pattern MK2 is removed after the word lines 210 are formed.

Then, referring to FIG. 3A and FIG. 3B and FIG. 8A and FIG. 8B, an insulation material is filled into the recesses 220t to form an insulation layer 220 embedded in the substrate 100 on each word line 210. As shown in FIG. 3A, the insulation layer 220 is embedded in the isolation structure 102 of the substrate 100 in the pick-up region PR. Then, the conductive contacts CT1 and CT2 are formed on the second section of each word line 210 in the pick-up region PR.

In summary, in the semiconductor structure and the method for forming the same according to the aforementioned embodiments, the second sections of the word lines in the pick-up region are designed to include a portion having a different level height from the first sections of the word lines in the cell region. As such, the gap or the spacing between the conductive contact in contact with the portion of the word line and other word line adjacent thereto can be improved, and thereby lowering the critical dimension (CD) and overlap requirements for the conductive contact, so as to enhance the process margin of the conductive contact.

What is claimed is:

1. A semiconductor structure, comprising:
a substrate comprising a cell region and a pick-up region adjacent to the cell region;
a plurality of word lines, arranged in a first direction and each extending in a second direction different from the first direction, wherein each of the word lines is embedded in the substrate and crosses the cell region and the pick-up region, and each of the word lines comprises a first section located in the cell region and a second section located in the pick-up region;
an insulation layer disposed on each of the word lines and embedded in the substrate; and
a conductive contact disposed on the second section of each word line,
wherein the first section comprises a first top surface in contact with the insulation layer, and the second section comprises a second top surface in contact with the conductive contact and a third top surface in contact with the insulation layer, wherein a level height of the second top surface is different from a level height of the first top surface.

2. The semiconductor structure of claim 1, wherein the level height of the second top surface is higher than the level height of the first top surface.

3. The semiconductor structure of claim 2, wherein the level height of the second top surface is different from a level height of the third top surface.

4. The semiconductor structure of claim 3, wherein the level height of the second top surface is higher than the level height of the third top surface.

5. The semiconductor structure of claim 1, wherein a dimension of each word line in the first direction gradually decreases along a third direction away from a top surface of the substrate.

6. The semiconductor structure of claim 5, wherein the level height of the second top surface is lower than the level height of the first top surface.

7. The semiconductor structure of claim 6, wherein the level height of the second top surface is the same as a level height of the third top surface.

8. The semiconductor structure of claim 1, wherein the second section comprises a first portion in contact with the insulation layer and a second portion protruding from the first portion, being in contact with the conductive contact, and surrounded by the insulation layer.

9. A method of forming a semiconductor structure, comprising:
providing a substrate comprising a cell region and a pick-up region adjacent to the cell region;
forming a plurality of word lines in the substrate, wherein the plurality of word lines are arranged in a first direction and each extending in a second direction different from the first direction, wherein each of the word lines crosses the cell region and the pick-up region and comprises a first section formed in the cell region and a second section formed in the pick-up region;
forming an insulation layer embedded in the substrate on each of the word lines; and
forming a conductive contact on the second section of each word line,
wherein the first section comprises a first top surface in contact with the insulation layer, and the second section comprises a second top surface in contact with the conductive contact and a third top surface in contact with the insulation layer, and a level height of the second top surface is different from a level height of the first top surface.

10. The method of claim 9, wherein a step of forming the word lines comprises:
forming a plurality of word line trenches in the substrate, wherein the plurality of word line trenches are arranged in the first direction and each extending in the second direction, and each of the word line trenches crosses the cell region and the pick-up region;
filling a word line material layer in each word line trench;
forming a mask pattern on the word line material layer in each word line trench, so as to cover a portion of the word line material layer corresponding to a position of the conductive contact; and
removing a portion of the word line material layer exposed by the mask pattern to form the plurality of word lines.

11. The method of claim 9, wherein a step of forming the word lines comprises:
forming a plurality of word line trenches in the substrate, wherein the plurality of word line trenches are arranged in the first direction and each extending in the second direction, and each of the word line trenches crosses the cell region and the pick-up region;
filling a word line material layer in each word line trench;
forming a mask pattern covering a portion of the word line material layer in each word line trench located in the cell region; and
removing a portion of the word line material layer exposed by the mask pattern located in the pick-up region to form the plurality of word lines.

12. The method of claim 9, wherein the level height of the second top surface is higher than the level height of the first top surface.

13. The method of claim 12, wherein the level height of the second top surface is different from a level height of the third top surface.

14. The method of claim 13, wherein the level height of the second top surface is higher than the level height of the third top surface.

15. The method of claim 9, wherein a dimension of each word line in the first direction is formed to gradually decrease in a third direction away from a top surface of the substrate.

16. The method of claim 15, wherein the level height of the second top surface is lower than the level height of the first top surface.

17. The method of claim 16, wherein the level height of the second top surface is the same as a level height of the third top surface.

18. The method of claim 10, wherein the second section comprises a first portion in contact with the insulation layer and a second portion protruding from the first portion, being in contact with the conductive contact, and surrounded by the insulation layer.
